(19) United States
(12) Patent Application Publication
(10) Pub. No.: US 2007/0011545 A1
(43) Pub. Date: Jan. 11, 2007

(54) SYSTEM AND METHOD FOR TESTING A NAS

(75) Inventors: CHAO-TSUNG FAN, TUCHENG (TW); WEN-CHIEN CHOU, TUCHENG (TW); CHIH-CHIANG LIU, TUCHENG (TW); CHUN-TE YEH, TUCHENG (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/308,574

(22) Filed: Apr. 8, 2006

(30) Foreign Application Priority Data
Jun. 3, 2005 (CN) 200510035141.8

(51) Int. Cl. G01R 31/28; G06F 11/00

(52) U.S. Cl. 714/742

(57) ABSTRACT

A system for testing a NAS includes: a data storage device (3) connected with a NAS (6) for storing function test program and test data; a host computer (1) connected with the NAS being used to issue commands for the NAS to self-test itself via the function test program and test data; and at least one USB flash memory (4) connected with the NAS for testing the PCI ports of the NAS. A method for testing a NAS is also disclosed.

### FIELD OF THE INVENTION

The present invention generally relates to systems and methods for testing storages, and more particularly to a system and method for testing a network attached storage (NAS).

### DESCRIPTION OF RELATED ART

Manufacturers of computer systems commonly use software-based analysis tools to measure performances of their products. These analyzing tools typically measure performance in the data throughput or the bandwidth of computer systems. For example, a bandwidth measurement may be taken by reading or writing data to a hard drive while timing the read or write operations.

Besides bandwidth, performance of data quality is also important to computer systems. In most cases, high bandwidth is irrelevant if data arrives incorrectly. Just as the slowest device in the data path may cause a loss of bandwidth, a single device along the data path that corrupts data may cause a decrease of data quality. As a result, manufacturers need to pay more attention not only to bandwidth of their network products, but also to the data quality of their network products.

Further more, manufacturers spend a significant amount of time loading in a test file in a product at the test mode stage of the assembly line. Once any network product is ready to be tested, the test file of the network product has to be loaded and used to test the network product. In other words, the time spent by manufacturers for loading the test file in every product to be tested is huge.

What is needed, therefore, is a system and method which monitor files to be printed automatically.

### SUMMARY OF INVENTION

A system for testing a network attached storage in accordance with a preferred embodiment includes a data storage device linked with a NAS, a host computer linked with the NAS, and at least one universal serial bus (USB) flash memory linked with the NAS. The data storage device is used for storing a function test program and test data. The host computer is used to issue commands for the NAS to self-test itself via the function test program and the test data. The USB flash memory is used for testing the peripheral component interconnect (PCI) ports of the NAS.

A method for testing a NAS in accordance with a preferred embodiment includes the steps of: examining whether all light emitting diodes of the NAS are working normally; reading a function test program and test data from a data storage device if all light emitting diodes of the NAS are working normally; and testing the components of the NAS via the function test program and the test data.

Other advantages and novel features of the present invention will become more apparent from the following detailed description of preferred embodiments when taken in conjunction with the accompanying drawings.

### BRIEF DESCRIPTION OF DRAWINGS

FIG. 1 is a schematic diagram of hardware configuration of a system for testing a NAS in accordance with a preferred embodiment;

FIG. 2 is a schematic diagram of main function modules of a host computer of the system of FIG. 1;

FIG. 3 is a schematic diagram of main function modules of a function test program;

FIG. 4 is a flowchart of a method for testing a NAS in accordance with a preferred embodiment; and

FIG. 5 is a flowchart of a method for testing components of a NAS of FIG. 5.

### DETAILED DESCRIPTION

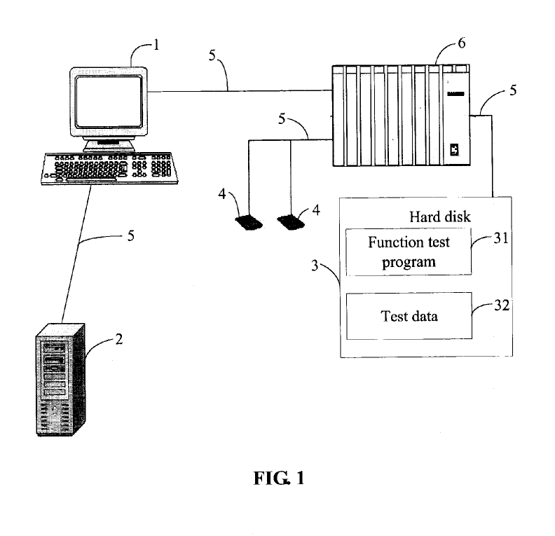

FIG. 1 is a schematic diagram of hardware configuration of a system for testing a NAS (hereinafter, “the system”) in accordance with a preferred embodiment. The system includes: a host computer 1 installed with an operating system (e.g. Linux) and connected to a NAS 6 via a data link 5, a server 2 connected with the host computer 1 via a data link 5, a data storage device 3 connected with the NAS 6 via a data link 5, and a plurality of USB flash memories 4 (only two shown) connected with the NAS 6 via a data link 5. The host computer 1 is used for controlling the NAS 6 to test components thereof, and exchanging data with the server 2. The data storage device 3 typically includes a region for storing the function test program 31 so that a NAS 6 can self-test the components within itself, and a region for storing test data 32. The USB flash memories 4 are used for testing the peripheral component interconnect (hereinafter, “PCI”) ports of the system.

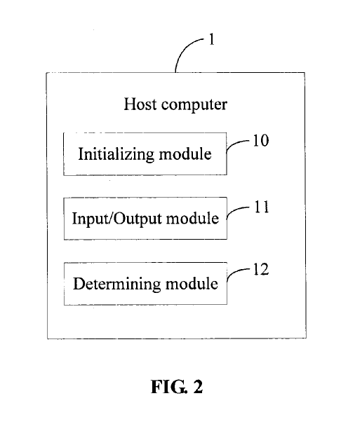

FIG. 2 is a schematic diagram of main function modules of the host computer 1. The host computer 1 typically includes an initializing module 10, an input/output module 11, and a determining module 12.

The initializing module 10 is used for booting and activating the system to test a NAS, such as the NAS 6.

The input/output module 11 is used for reading a serial-number of the NAS 6, transmitting the serial-number to the server 2, booting the NAS 6 to read the function test program 31 and test data 32 from data storage device 3, and controlling the NAS 6 to execute the function test program 31. Furthermore, the input/output module 11 is used for outputting test results through a display device or a monitor of the host computer 1. Moreover, the input/output module 11 is used for transmitting the test results to the server 2. The serial-number and test results are received and stored by the server 2.

The determining module 12 is used for providing a selection box with two options Y and N; a user interface to record whether a light emitting diode of the NAS 6 is working normally. In other words, the user selects the option N if a light emitting diode of the NAS 6 is working abnormally, otherwise, the user selects the option Y. The determining module 12 is further used for determining whether the components of the NAS 6 are working normally, and providing another selection box with two options Y and N; a user interface to input whether another NAS is ready to be tested. In the preferred embodiment, the components of the NAS 6 typically include data storage components and PCI ports. The USB flash memories 4 are linked with the NAS 6 via the PCI ports.

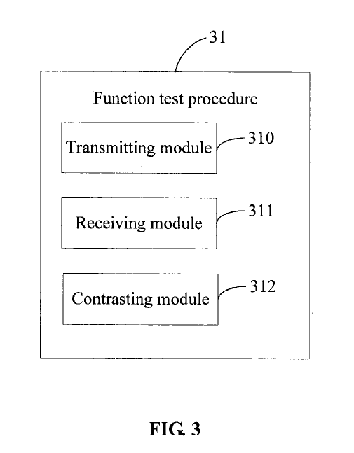

FIG. 3 is a schematic diagram of main function modules of the function test program 31. The function test program 31 typically includes a transmitting module 310, a receiving module 311, and a contrasting module 312. The transmitting module 310 is used for transmitting the test data 32 read from the data storage device 3 to the data storage components of the NAS 6 and to the USB flash memories 4 via the PCI ports of the NAS 6. The receiving module 311 is used for reading and receiving examining data from the components. The data storage components and the USB flash memories 4 receive the test data 32 transmitted by the transmitting module 310, and store the test data 32 as examining data. The contrasting module 312 is used for comparing the test data 32 with the examining data, and returning a comparison result.

The determining module 12 is used for determining whether the components of the NAS 6 are working normally according to the comparison result by the contrasting module 312. The components of the NAS 6 are working normally if the test data is the same as the examining data, otherwise, the components of the NAS 6 are working abnormally. In other words, the determining module 12 is used for determining whether the test data is the same as the examining data.

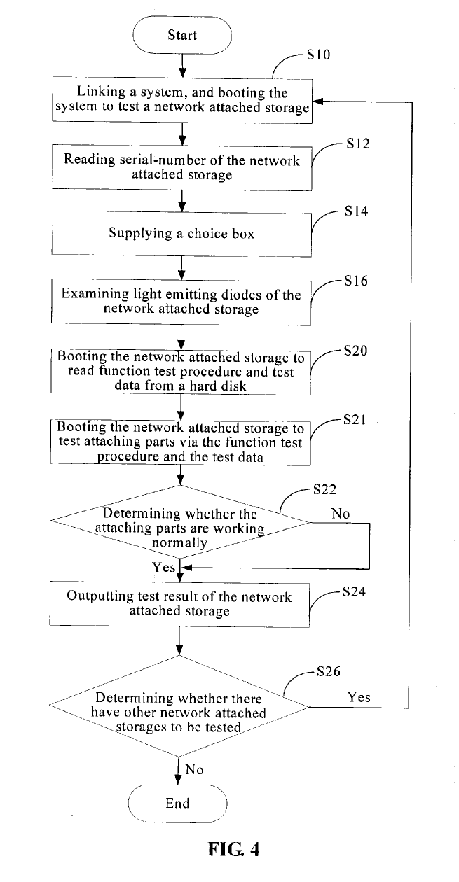

FIG. 4 is a flowchart of a method for testing a NAS in accordance with the preferred embodiment. A tester may use the system to test the NAS 6. In step S10, the tester connects the host computer 1 with the server 2 and the NAS 6 with data link 5, connects the NAS 6 with the data storage device 3 and the USB flash memories 4 with data link 5, and activates the initializing module 10 in the host computer 1. The initializing module 10 initializes the system to test the NAS 6. In step S12, the input/output module 11 reads the serial-number of the NAS 6, and transmits the serial-number to the server 2. In step S14, the determining module 12 provides a selection box for the user. In step S16, the user records whether a light emitting diode of the NAS 6 is working normally by using the selection box provided by the host computer 1. If all light emitting diodes of the NAS 6 are working normally, in step S20, the input/output module 11 boots the NAS 6 to read the function test program 31 and the tests data 32 from the data storage device 3. In step S21, the input/output module 11 controls the NAS 6 to execute the function test program 31 so that the NAS 6 tests its components thereof. Otherwise, if any light emitting diode of the NAS 6 is working abnormally, in step S24, the input/output module 11 outputs a test result that indicates the NAS 6 works at fault through a display device or a monitor of the host computer 1 and transmits the test result to the server 2. In step S22, the determining module 12 determines whether the components are working normally. If the components are working normally, in step S24, the input/output module 11 outputs a test result that indicates the NAS 6 is in good working order through the display device of the host computer 1, and transmits the test result to the server 2. Otherwise, if the components are working abnormally, in step S24, the input/output module 11 outputs a test result that indicates the NAS 6 works at fault through the display device of the host computer 1, and transmits the test result to the server 2. In step S26, the determining module 12 provides another selection box to the user. The user determines whether another NAS 6 is ready to be tested by using the selection box. If there is another NAS 6 ready to be tested, the procedure returns to step S10 described above. Otherwise, if there is no other NAS 6 ready to be tested, the procedure ends.

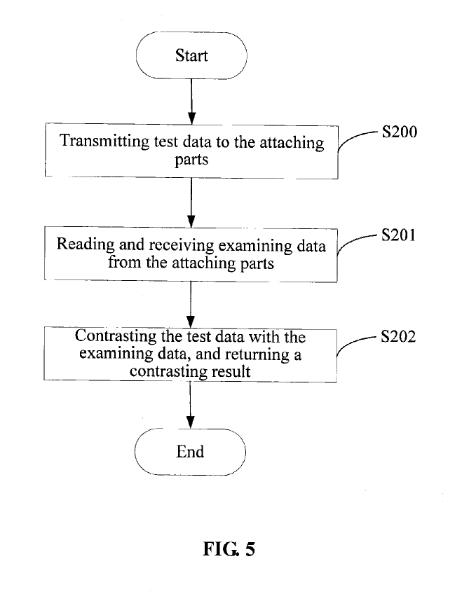

FIG. 5 is a flowchart of a method for testing the components of the NAS 6. In step S200, the transmitting module 310 transmits the test data 32 read from the data storage device 3 to the data storage component of the NAS 6 and to the USB flash memories 4 via the PCI ports of the NAS 6. In step S201, the receiving module 311 reads and receives examining data from the data storage components and the USB flash memories 4 via the PCI ports. In step S202, the contrasting module 312 compares the test data with the examining data, and returns the comparison result.

Although the present invention has been specifically described on the basis of a preferred embodiment and a preferred method, the invention is not to be construed as being limited thereto. Various changes or modifications may be made to said embodiment and method without departing from the scope and spirit of the invention.

What is claimed is:

1. A system for testing a NAS, the system comprising:
a data storage device connected with the NAS for storing a function test program and test data;
a host computer connected with the NAS being used to issue commands for the NAS to self-test itself via the function test program and the test data; and
at least one USB flash memory connected with the NAS for testing the PCI ports of the NAS.

2. The system as claimed in claim 1, wherein the host computer comprises:
an initializing module for booting and activating the system for testing the NAS;
an input/output module for reading the serial-number of the NAS, booting the NAS to read the function test program and the test data from the data storage device, and controlling the NAS to test the components via the function test program and the test data; and
a determining module for providing two selection boxes, and determining whether the components are working normally.

3. The system as claimed in claim 2, wherein the input/output module is further used for outputting a test result of the NAS.

4. The system as claimed in claim 2, wherein the function test program comprises:
a transmitting module for transmitting the test data to the data storage components of the NAS and to the USB flash memory via the PCI ports of the NAS;
a receiving module for reading and receiving examining data from the data storage components and the USB flash memory via the PCI ports; and
a contrasting module for comparing the test data with the examining data, and returning a comparison result.

5. A method for testing a NAS, the method comprising the steps of:
examining whether all light emitting diodes of the NAS are working normally;
reading a function test program and test data from a data storage device if all light emitting diodes of the NAS are working normally; and
testing components of the NAS via the function test program and the test data.

6. The method as claimed in claim 5, wherein the step of testing the components via the function test program and the test data comprises the steps of:
transmitting the test data to the data storage components of the NAS and the USB flash memory via the PCI ports of the NAS;
reading and receiving examining data from the data storage components and the USB flash memory via the PCI ports; and
comparing the test data with the examining data, and returning a comparison result.

7. The method as claimed in claim 6, further comprising the steps of:
determining whether the components are working normally according to the comparison result;
outputting a test result that indicates the NAS is in good working order if the components are working normally; or
outputting a test result that indicates the NAS works at fault if the components are working abnormally.
